(19) United States
(12) Patent Application Publication
(10) Pub. No.: US 2020/0137922 A1
(43) Pub. Date: Apr. 30, 2020

(54) TRANSMITTING APPARATUS AND PLUG-IN UNIT

(71) Applicant: FUJITSU LIMITED, Kawasaki-shi (JP)

(72) Inventors: Kazuhiro IINO, Yokohama (JP); Seiichiro Sato, Inagi (JP); TAKASHI SHIRAKAMI, Kawasaki (JP)

(73) Assignee: FUJITSU LIMITED, Kawasaki-shi (JP)

(21) Appl. No.: 16/569,788

(22) Filed: Sep. 13, 2019

(30) Foreign Application Priority Data
Oct. 30, 2018 (JP) 2018-203551

(51) Int. Cl. H05K 7/20; H01R 12/73; H01R 12/72; H05K 5/02

(52) U.S. Cl. CPC H05K 7/2049; H05K 5/0286; H01R 12/722; H01R 12/732

(57) ABSTRACT

A transmitting apparatus includes an apparatus main body, and a plug-in unit, wherein the apparatus main body includes a holding member that holds a cooling plate displaceably in an upward-downward direction in the slot of the apparatus main body, and the plug-in unit includes a casing allowed to be inserted and removed into and from the slot of the apparatus main body, a substrate that is housed in the casing and on which a heat generating, component is mounted, and a displacing member that displaces the cooling plate held by the holding member to a position at which the cooling plate gets contact with the heat generating component or a position at which the cooling plate gets contact with a heat transfer member disposed on the heat generating component in conjunction with operation of inserting the casing into the slot of the apparatus main body.

### CROSS-REFERENCE TO RELATED APPLICATION

This application is based upon and claims the benefit of priority of the prior Japanese Patent Application No. 2018-203551, filed on Oct. 30, 2018, the entire contents of which are incorporated herein by reference.

### FIELD

The embodiments discussed herein are related to a transmitting apparatus and a plug-in unit.

### BACKGROUND

There is a transmitting'apparatus of a plug-in type in which a plug-in unit (PIU) in which a heat generating component such as an electronic component is mounted is inserted into an apparatus main body. In such a transmitting apparatus, heat generated by the heat generating component becomes a factor causing an operation abnormality of the PIU and the transmitting apparatus. For this reason, it is important to cool the heat generating component in the transmitting apparatus.

As a technique for cooling a heat generating component, there is a technique in which the heat generating component is brought into contact with a cooling plate inside which a flow path of a cooling liquid is formed.

For example, as, a related art, Japanese Laid-open Patent Publication No. 2009-15869 and so forth are disclosed.

Incidentally, in a transmitting apparatus of the plug-in type, in the case of applying the cooling plate for a heat generating component in a PIU, it is conceivable that the cooling plate is attached directly to the heat generating component in the PIU. When the cooling plate is attached directly to the heat generating component in the PIU, a connector for a cooling liquid is disposed between the apparatus main body and the PIU and the cooling liquid is supplied to a conduit of the cooling plate through the connector for the cooling liquid. However, when the connector for the cooling liquid is disposed between the apparatus main body and the PIU, the connector for the cooling liquid occupies a comparatively-large space. For this reason, in the transmitting apparatus of the plug-in type, it becomes difficult to sufficiently ensure a space for mounting other components such as electrical connectors. Thus, it is expected to cool the heat generating component in the PIU without disposing the connector for the cooling liquid between the apparatus main body and the PIU.

In view of the above description, it is desirable to provide a transmitting apparatus and a plug-in unit that may cool a heat generating component in a PIU without disposing a connector for a cooling liquid between an apparatus main body and the PIU.

### SUMMARY

According to an aspect of the embodiment, a transmitting apparatus includes a transmitting apparatus includes an apparatus main body in which a slot is formed, and a plug-in unit configured to be inserted into the slot of the apparatus main body, wherein the apparatus main body includes a holding member that holds a cooling plate displaceably in an upward-downward direction in the slot of the apparatus main body, and the plug-in unit includes a casing allowed to be inserted and removed into and from the slot of the apparatus main body, a substrate that is housed in the casing and on, which a heat generating component is mounted, and a displacing member that displaces the cooling plate held by the holding member to a position at which the cooling plate gets contact with the heat generating component or a position at which the cooling plate gets contact with a heat transfer member disposed on the heat generating component in conjunction with operation of inserting the casing into the slot of the apparatus main body.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an appearance of a transmitting apparatus according to embodiment 1;

FIG. 2 is a top view illustrating one example of an internal configuration of an apparatus main body and a PIU included in a transmitting apparatus according to embodiment 1;

FIG. 3 is a side sectional view illustrating one example of an internal configuration of an apparatus main body and a PIU included in a transmitting apparatus according to embodiment 1;

FIG. 4 is a diagram explaining one example of a flow of operation of displacing, a cooling plate in embodiment 1;

FIG. 5 is a diagram explaining one example of a floe of operation of displacing a cooling plate in embodiment 1;

FIG. 6 is a diagram explaining one example of a flow of operation of displacing a cooling plate in embodiment 1;

FIG. 7 is a perspective view illustrating one example of an internal configuration of an apparatus main body and a PIU included in a transmitting apparatus according to embodiment 2;

FIG. 8 is a perspective view illustrating one example of a fixing form of a holding member in embodiment 2;

FIG. 9 is a perspective view illustrating one example of a fixing form of a displacing member in embodiment 2;

FIG. 10 is a sectional view along line X-X in FIG. 9;

FIG. 11 is a diagram explaining one example of a flow of operation of displacing a cooling plate in embodiment 2;

FIG. 12 is a diagram explaining one example of a flow of operation of displacing a cooling plate in embodiment 2;

FIG. 13 is a side view illustrating one example of an internal configuration of a PIU included in a transmitting apparatus according to embodiment 3;

FIG. 14 is a diagram explaining one example of a flow operation of displacing a cooling plate in embodiment 3;

FIG. 15 is a diagram explaining one example of operation of displacing a cooling plate in embodiment 3;

FIG. 16 is a side, view illustrating one example of an internal configuration of an apparatus main body and a PIU included in a transmitting apparatus according to a modification example of embodiment 3;

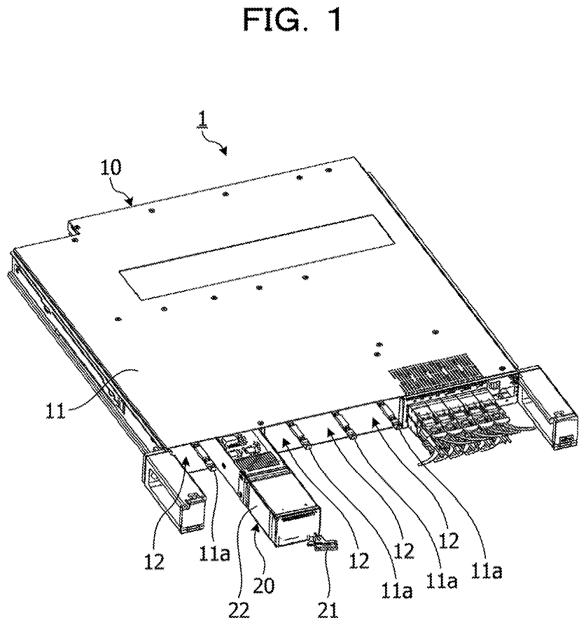

FIG. 1 is a side view illustrating one example of an internal configuration of an apparatus main body and a PIU included in a transmitting apparatus according to embodiment 4;

FIG. 18 is a perspective view illustrating one example of a holding form of a cooling plate in embodiment 4;

FIG. 19 is a diagram explaining one example o flow operation of displacing a cooling plate in embodiment 4;

FIG. 20 is a diagram explaining one example of flow of operation of displacing a cooling plate in embodiment 4;

FIG. 21 is a side view illustrating one example of an internal configuration of an apparatus main body and a PIU included in a transmitting apparatus according to embodiment 5;

FIG. 22 is a diagram explaining one example of a flow of operation of displacing a cooling plate in embodiment 5; and

FIG. 23 is a diagram explaining one example of operation of displacing a cooling plate in embodiment 5.

### DESCRIPTION OF EMBODIMENTS

Embodiments of a transmitting apparatus and a plug-in unit disclosed by the present application will be described in detail below based on the drawings. Disclosed techniques are not limited by these embodiments, Furthermore, configurations having the same function are given the same symbols in the embodiments and overlapping description is omitted.

### Embodiment 1

### [Configuration of Transmitting Apparatus 1]

FIG. 1 is a perspective view illustrating an appearance of a transmitting apparatus according to embodiment 1. An transmitting apparatus 1 illustrated in FIG. 1 is a transmitting apparatus of a plug-in type in which a plug-in unit (PIU) 20 in which a heat generating component such as an electronic component is mounted is inserted into an apparatus main body 10. The apparatus main body 10 includes a casing 11. The casing 11 is a box body including a bottom plate, a top plate opposed to the bottom plate, a pair of sidewalls opposed to each other, a front surface, and a back surface. Hereinafter, in FIG. 1, a surface located on the near side of the plane of paper is referred to as the front surface and a surface located on the far side of the plane of paper is referred to as the back surface.

Plural slots 12 are formed in the front surface of the casing 11. Each slot 12 of the front surface of the casing 11 is marked out by a rail 11a disposed on the bottom plate of the casing 11. The PIU 20 is inserted into each slot 12 of the front surface of the casing 11 along the rail 11a. Through the insertion of the PIU 20 into each slot 12 of the front surface of the casing 11 the PIU 20 is electrically coupled to the apparatus main body 10.

The PIU 20 includes a casing 22 that may be inserted and removed into and from the slot 12 of the apparatus main body 10 and a lever 21. The casing 22 is a box body including a bottom plate, a top plate opposed to the bottom plate, a pair of sidewalls opposed to each other, a front surface, and a back surface. In the front surface of the casing 22 an opening (not illustrated) into which a pluggable optical module that transmits n receives an optical signal is inserted is formed.

The lever 21 is a lever that is pivotally disposed on the casing 22 and is operated at the time of operation of inserting the casing 22. The lever 21 has a function as leverage. For example, when the casing 22 is inserted into the slot 12 of the apparatus main body 10, the lever 21 is made to pivot by operation by an operator and a force in the insertion direction of the casing 22 is given to the apparatus main body 10 through the lever 21 by action of leverage. Thereby, the casing 22 is inserted into the slot 12 of the apparatus main body 10.

### [Internal Configuration of Apparatus Main Body 10 and PIU 20]

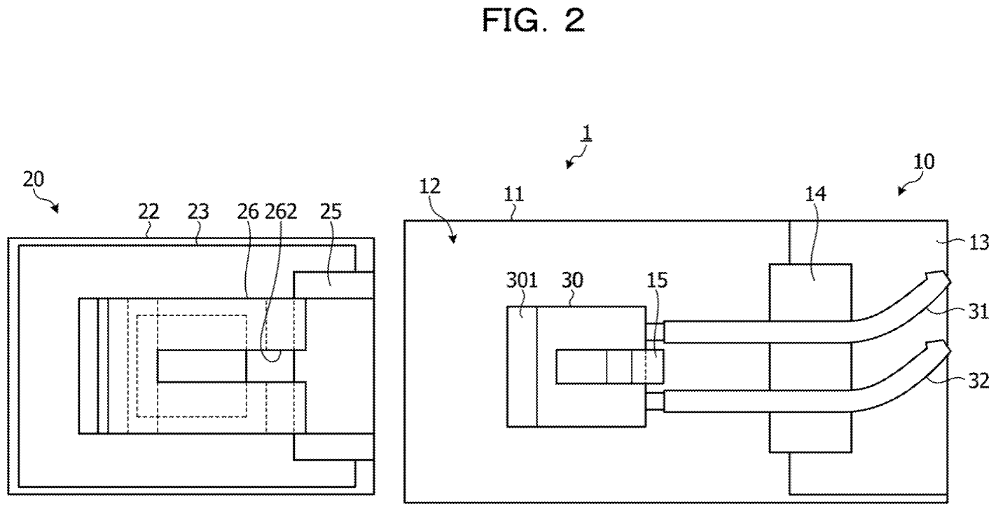

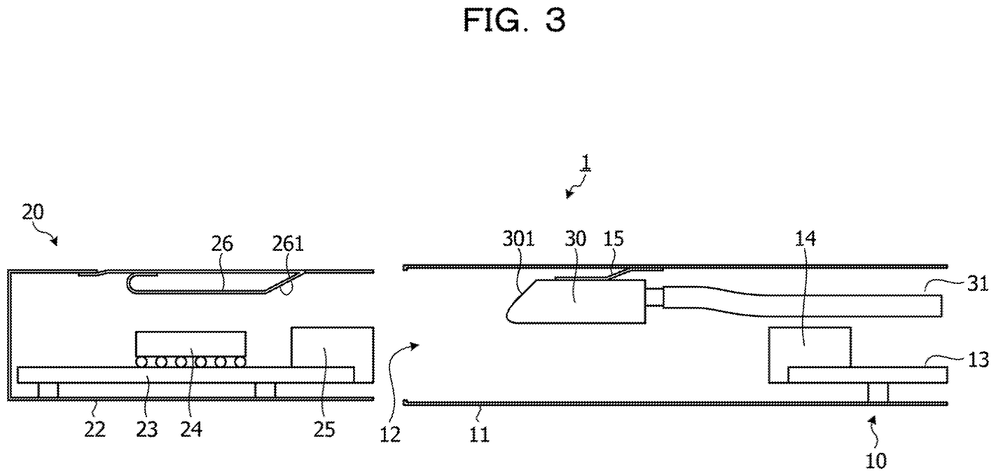

FIG. 2 is a top view illustrating one example of an internal configuration of an apparatus main body and a PIU included in a transmitting apparatus according to embodiment 1. FIG. 3 is a side sectional view illustrating one example of an internal configuration of an apparatus main body and a PIU included in a transmitting apparatus according to embodiment 1. The transmitting apparatus, the apparatus main body, and the PIU illustrated in FIG. 2 and FIG. 3 may be the transmitting apparatus 1, the apparatus main body 10, and the PIU 20, respectively, illustrated in FIG. 1. In FIG. 2 and FIG. 3, the state in which the casing 22 of the PIU 20 has been withdrawn from the slot 12 of the apparatus main body 10 is illustrated. In FIG. 2, the top plate of the casing 11 of the apparatus main body 10 and the top plate of the casing 22 of the PIU 20 are omitted for convenience of description.

As illustrated in FIG. 2 and FIG. 3, a substrate 13 that is a printed circuit board is housed inside the casing 11 of the apparatus main body 10. The substrate 13 is cut in such a manner as to avoid the slot 12 of the apparatus main body 10 and an electrical connector 14 is disposed opposed to the slot 12 on the upper surface of the substrate 13. The electrical connector 14 is coupled to an electrical connector 25 of the PIU 20 in the state in which the casing 22 of the PIU 20 is inserted in the slot 12 of the apparatus main body 10.

A holding member 15 is fixed to the top plate of the casing 11 of the apparatus main body 10. The holding member 15 holds a cooling plate 30 displaceably in the upward-downward direction in the slot 12 of the apparatus main body 10. The holding member 15 holds the cooling plate 30 at a position higher than the electrical connector 14 and the electrical connector 25 in the slot 12 of the apparatus main body 10. For example, in the slot 12 of the apparatus main body 10, the holding member 15 holds the cooling plate 30 at a position that does not overlap with a path for coupling the electrical connector 14 and the electrical connector 25. Due to this, when the casing 22 of the PIU 20 is inserted into the slot 12 of the apparatus main body 10, interference between the electrical connector 25 to be coupled to the electrical connector 14 and the cooling plate 30 is avoided. In the present embodiment, the holding member 15 is a plate spring, for example.

The cooling plate 30 is formed into a flat plate shape by a thermally conductive material such as copper or aluminum, for example. A flow path in which a cooling liquid such as water is made to pass and flow is formed inside the cooling plate 30. An inlet conduit 31 for supplying the cooling liquid and an outlet conduit 32 for discharging the cooling liquid are coupled to the flow path in the cooling plate 30. Furthermore, the cooling plate 30 includes an inclined surface 301 that gets more separated from the top plate of the casing 11 as getting closer to the tip of the cooling plate 30.

A substrate 23 that is a printed circuit board is housed inside the casing 22 of the PIU 20. An electronic component 24 is mounted on the upper surface of the substrate 23. The electronic component 24 is a heat generating component that generates heat at the time of operation. Furthermore, the electrical connector 25 is disposed in a region located on the back surface side of the casing 22 in the upper surface of the substrate 23. The electrical connector 25 is coupled to the electrical connector 14 in the apparatus main body 10 in the state in which the casing 22 of the PIU 20 is inserted in the slot 12 of the apparatus main body 10.

Furthermore, the PIU 20 includes a displacing member 26. The displacing member 26 is fixed to the region opposed to the electronic component 24 in the top plate of the casing 22. The displacing member 26 displaces the cooling plate 30 held by the holding member 15 to a position at which the cooling plate 30 gets contact with the electronic component 24 in conjunction with operation of inserting the casing 22 into the slot 12 of the apparatus main body 10. For example, in conjunction with the operation of inserting the casing 22, the displacing member 26 displaces the cooling plate 30 held by the holding member 15 from the position higher than the electrical connector 14 and the electrical connector 25 to the position at which the cooling plate 30 gets contact with the electronic component 24. In the present embodiment, the displacing member 26 is a plate spring and displaces the cooling plate 30 to the position at which the cooling, plate 30 gets contact with the electronic component 24 by elastically pressing the cooling plate 30 held by the holding member 15 in a direction toward the electronic component 24 in conjunction with the operation of inserting the casing 22.

Furthermore, the displacing member 26 includes an inclined surface 261 and guides the cooling plate 30 in the direction toward the electronic component 24 by bringing the inclined surface 261 into contact with the inclined surface 301 of the cooling plate 30 when the casing 22 of the PIU 20 is inserted into the slot 12 of the apparatus main body 10. Moreover, a notch part 262 is formed at part of the displacing member 26 and the holding member 15 held by the cooling plate 30 is housed in the notch part 262 of the displacing member 26 when the casing 22 of the PIU 20 is inserted into the slot 12 of the apparatus main body 10.

### [Operation and Effects]

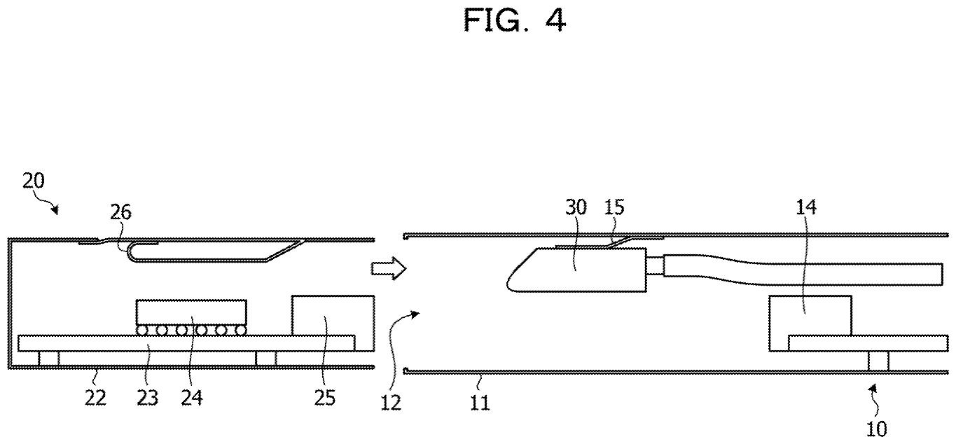

Next, operation and effects of the, transmitting apparatus 1 according to the present embodiment will be described. FIG. 4 to FIG. 6 are diagrams explaining one example of the flow of operation of displacing the cooling plate 30 in embodiment 1. FIG. 4 illustrates the state in which the casing 22 of the PIU 20 has not yet been inserted into the slot 12 of the apparatus main body 10. In this state, the holding member 15 holds the cooling plate 30 at the position higher than the electrical connector 14 and the electrical connector 25 in the slot 12 of the apparatus main body 10. Subsequently, insertion of the casing 22 of the PIU 20 into the slot 12 of the apparatus main body 10 is started. In the example of FIG. 4, the insertion direction of the casing 22 of the PIU 20 is indicated by a white arrow.

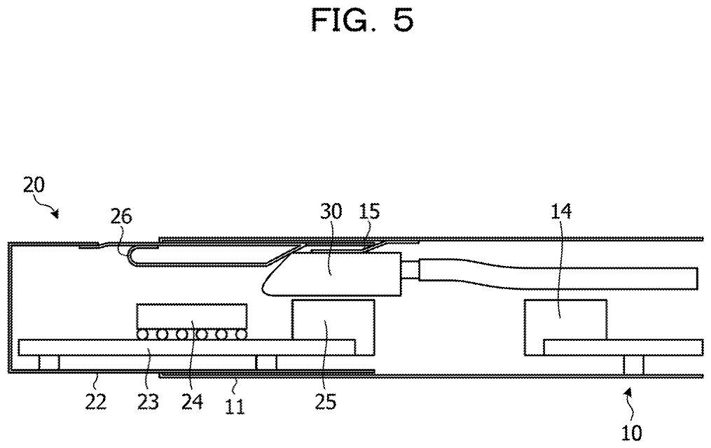

FIG. 5 illustrates the state in which part of the casing 22 of the PIU 20 has been inserted into the slot 12 of the apparatus main body 10. In this state, the cooling plate 30 held by the holding member 15 is inserted in the gap between the electrical connector 25 and the top plate of the casing 22. The displacing member 26 displaces the cooling plate 30 held by the holding member 15 from the position higher than the electrical connector 14 and the electrical connector 25 to the position at which the cooling plate 30 gets contact with the electronic component 24 in conjunction with the operation of inserting the casing 22. In the example of FIG. 5, the displacing member 26 displaces the cooling plate 30 to the position at which the cooling plate 30 gets contact with the electronic component 24 by elastically pressing the cooling plate 30 held by the holding member 15 in a direction toward the electronic component 24.

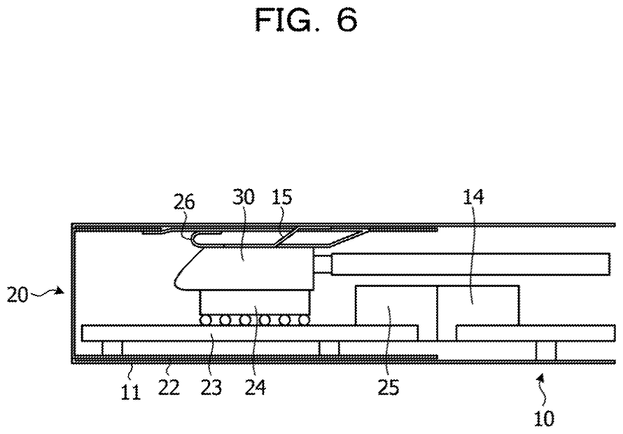

FIG. 6 illustrates the state in which the casing 22 of the PIU 20 has been completely inserted into the slot 12 of the apparatus main body 10. In this state, the electrical connector 14 and the electrical connector 25 are coupled and the cooling plate 30 is in tight contact with the electronic component 24 due to the pressing by the displacing member 26.

Due to this, the transmitting apparatus 1 may start cooling of the electronic component 24 in the PIU 20 in conjunction with the operation of inserting the casing 22 of the PIU 20 into the slot 12 of the apparatus main body 10. As a result, the transmitting apparatus 1 may cool the heat generating component in the PIU 20.

For example, in the transmitting apparatus 1 of the plug-in type, in the case of applying the cooling plate 30 for the heat generating component in the PIU 20, it is conceivable that the cooling plate 30 is attached directly to the heat generating component in the PIU 20. When the cooling plate 30 is attached directly to the heat generating component in the PIU 20, a connector for the cooling liquid is disposed between the apparatus main body 10 and the PIU 20 and the cooling liquid is supplied to a conduit of the cooling plate 30 through the connector for the cooling liquid. However, when the connector for the cooling liquid is disposed between the apparatus main body 10 and the PIU 20, the connector for the cooling liquid occupies a comparatively-large space. For this reason, in the transmitting apparatus 1 of the plug-in type, it becomes difficult to sufficiently ensure a space for mounting other components such as the electrical connector 14 and the electrical connector 25.

Thus, in the transmitting apparatus 1, the displacing member 26 displaces the cooling plate 30 held by the holding member 15 to the position at which the cooling plate 30 gets contact with the electronic component 24 in conjunction with the operation of inserting the casing 22 into the slot 12 of the apparatus main body 10. Due to this, the transmitting apparatus 1 may start cooling of the electronic component 24 in the PIU 20 in conjunction with the operation of inserting the casing 22 of the PIU 20 into the slot 12 of the apparatus main body 10. Thus, the connector for the cooling liquid between the apparatus main body 10 and the PIU 20 may be omitted. As a result, the transmitting apparatus 1 may cool the heat generating component in the PIU 20 without disposing the connector for the cooling liquid between the apparatus main body 10 and the PIU 20.

As described above, in the transmitting apparatus 1 and the PIU 20 according to the present embodiment, the displacing member 26 displaces the cooling plate 30 held by the holding member 15 to the position at which the cooling plate 30 gets contact with the electronic component 24 in conjunction with the operation of inserting the casing 22 into the slot 12 of the apparatus main body 10.

According to the configuration of the transmitting apparatus 1 and the PIU 20, the heat generating component in the PIU 20 may be cooled without disposing the connector for the cooling liquid between the apparatus main body 10 and the PIU 20.

### Embodiment 2

A transmitting apparatus 1A according to embodiment 2 has a configuration similar to that of the transmitting apparatus 1 of embodiment 1 mainly except for that a heat transfer member is disposed on a heat generating component and the cooling plate 30 is displaced to such a position as to get contact with the heat transfer member. Therefore, in embodiment 2, the same reference symbol is used for a constituent element common to the above-described embodiment 1 and detailed description thereof is omitted.

### [Internal Configuration of Apparatus Main Body 10 and PIU 20]

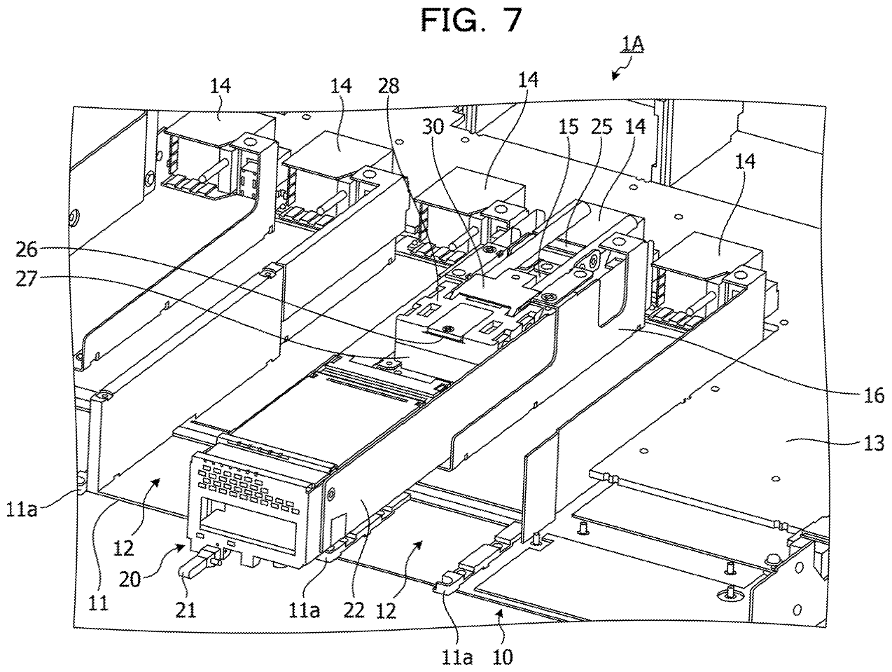

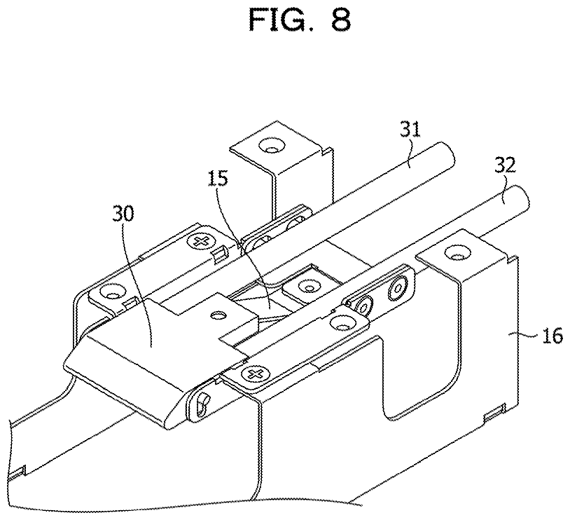

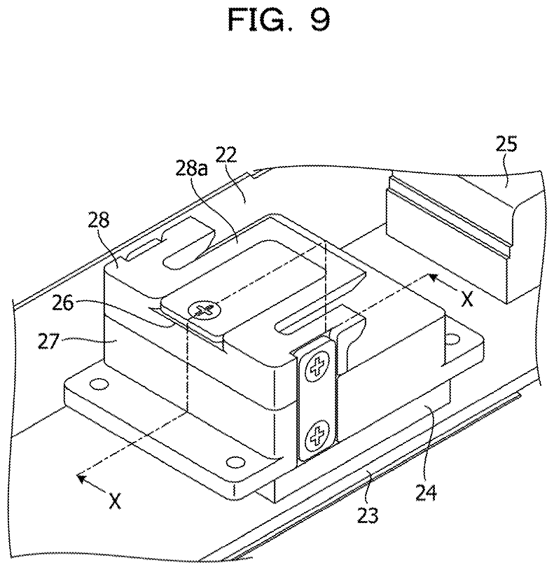

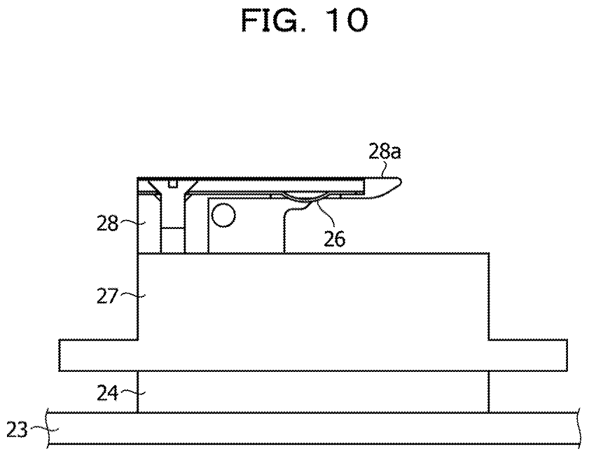

FIG. 7 is a perspective view illustrating one example of an internal configuration of an apparatus main body and a PIU included in a transmitting apparatus according to embodiment 2. FIG. 8 is a perspective view illustrating one example of the fixing form of the holding member 15 in embodiment 2, FIG. 9 is a perspective view illustrating one example of the fixing form of the displacing member 26 in embodiment 2. FIG. 10 is a sectional view along line X-X in FIG. 9. In FIG. 7, the state in which the casing 22 of the PIU 20 is inserted in the slot 12 of the apparatus main body 10 is illustrated. In FIG. 7, the top plate of the casing 11 of the apparatus main body 10 is omitted for convenience of description.

In the transmitting apparatus 1A illustrated in FIG. 7, the holding member 15 is fixed to a fixed member 16. As illustrated in FIG. 8, the fixed member 16 has a shape corresponding to the slot 12 of the apparatus main body 10 and is fixed to the bottom surface of the slot 12 of the apparatus main body 10. The holding member 15 is fixed to the fixed member 16 at a position near the top plate of the casing 11 of the apparatus main body 10. Then, the holding member 15 holds the cooling plate 30 displaceably in the upward-downward direction in the slot 12 of the apparatus main body 10. In the present embodiment, the holding member 15 is a plate spring, for example.

Furthermore, in the transmitting apparatus 1A illustrated in FIG. 7, the PIU 20 includes a heat transfer member 27. As illustrated in FIG. 9 and FIG. 10, the heat transfer member 27 is disposed on the electronic component 24. The heat transfer member 27 is formed into a flat plate shape by a thermally conductive material such as copper or aluminum, for example. A fixed member 28 is disposed on the upper surface of the heat transfer member 27.

The fixed member 28 includes an opposed part 28a opposed to the upper surface of the heat transfer member 27. When the casing 22 of the PIU 20 is inserted into the slot 12 of the apparatus main body 10, the fixed member 28 guides the cooling plate 30 in a direction, toward the electronic component 24 by bringing the, opposed part 28a into contact with the inclined surface 301 of the cooling plate 30. In the present embodiment, the displacing member 26 is fixed to the opposed part 28a of the fixed member 28. Then, the displacing member 26 displaces the cooling plate 30 held by the holding member 15 to a position at which the cooling, plate 30 gets contact with the heat transfer member 27 in conjunction with operation of inserting the casing 22 into the slot 12 of the apparatus main body 10. For example, in conjunction with the operation of inserting the casing 22, the displacing member 26 displaces the cooling plate 30 held by the holding member 15 from a position higher than the electrical connector 14 and the electrical connector 25 to the position at which the cooling plate 30 gets contact with the heat transfer member 27. In the present embodiment, the displacing member 26 is a plate spring and displaces the cooling plate 30 to the position at which the cooling plate 30 gets contact with the heat transfer member 27 by elastically pressing the cooling plate 30 held by the holding member 15 in the direction toward the electronic component 24 in conjunction with the operation of inserting the casing 22.

### [Operation and Effects]

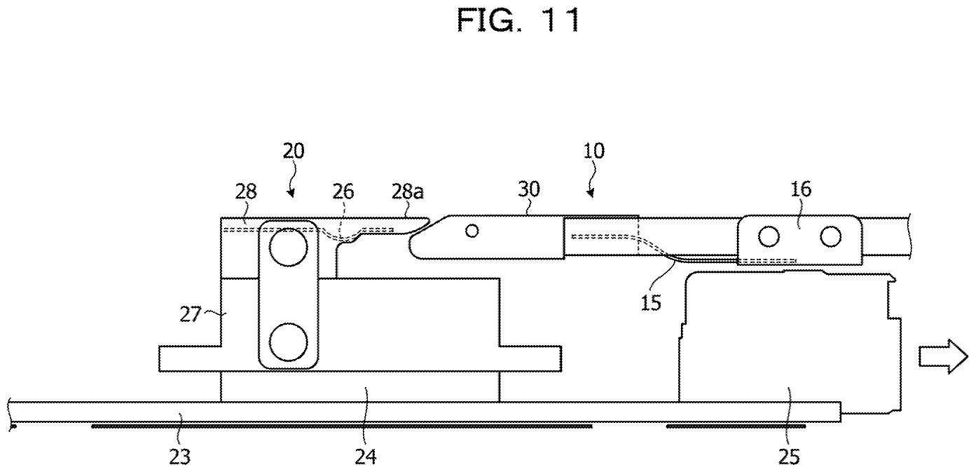

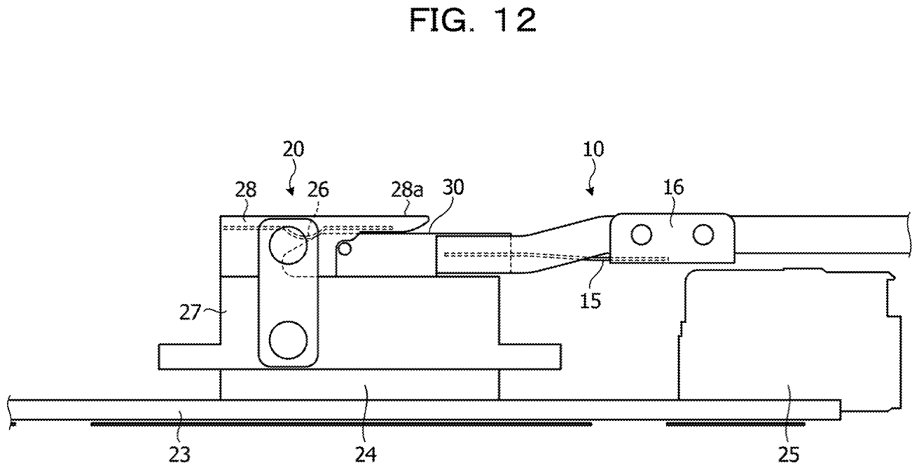

Next, operation and effects of the transmitting, apparatus 1A according to the present embodiment will be described. FIG. 11 and FIG. 12 are diagrams explaining one example of the flow of operation of displacing the cooling plate 30 in embodiment 2. In FIG. 11 and FIG. 12, the casing 11 of the apparatus main body 10 and the casing 22 of the PIU 20 are omitted for convenience of description. In the state in which the, casing 22 of the PIU 20 has not yet been inserted into the slot 12 of the apparatus main body 10, the holding member 15 holds the cooling plate 30 at the position higher than the electrical connector 14 and the electrical connector 25 in the slot 12 of the apparatus main body 10. First, insertion of the casing 22 of the PIU 20 into the slot 12 of the apparatus main body 10 is started. In FIG. 11, the insertion direction of the casing 22 of the PIU 20 is indicated by a white arrow.

FIG. 11 illustrates the state in which part of the casing 22 of the PIU 20 has been inserted into the slot 12 of the apparatus main body 10. In this state, the cooling plate 30 held by the holding member 15 is inserted in the gap between the electrical connector 25 and the top plate of the casing 22. The displacing member 26 displaces the cooling plate 30 held by the holding member 15 from the position higher than the electrical connector 14 and the electrical connector 25 to the position at which the cooling plate 30 gets contact with the heat transfer member 27 in conjunction with the operation of inserting the casing 22. In the example of FIG. 11, the displacing member 26 displaces the cooling plate 30 to the position at which the cooling plate 30 gets contact with the heat transfer member 27 by elastically pressing the cooling plate 30 held by the holding member 15 in a direction toward the electronic component 24.

FIG. 12 illustrates the state in which the casing 22 of the PIU 20 has been completely inserted into the slot 12 of the apparatus main body 10. In this state, the cooling, plate 30 is in tight contact with the heat transfer member 27 due to the pressing by the displacing member 26.

As described above, in the transmitting apparatus 1A according to the present embodiment, the PIU 20 includes the heat transfer member 27. The displacing member 26 displaces the cooling plate 30 held by the holding member 15 to the position at, which the cooling plate 30 gets contact with the heat transfer member 27 in conjunction with the operation of inserting the casing 22 into the slot 12 of the apparatus main body 10.

According to the configuration of the transmitting apparatus 1A, the cooling plate 30 may be brought into indirect contact with the heat generating component with the intermediary of the heat transfer member 27. Thus, the amount of displacement of the cooling plate 30 may be decreased by the amount corresponding to the thickness of the heat transfer member 27.

### Embodiment 3

Embodiment 3 relates to a variation of the displacing member of embodiment 2.

### [Internal Configuration of PIU 20]

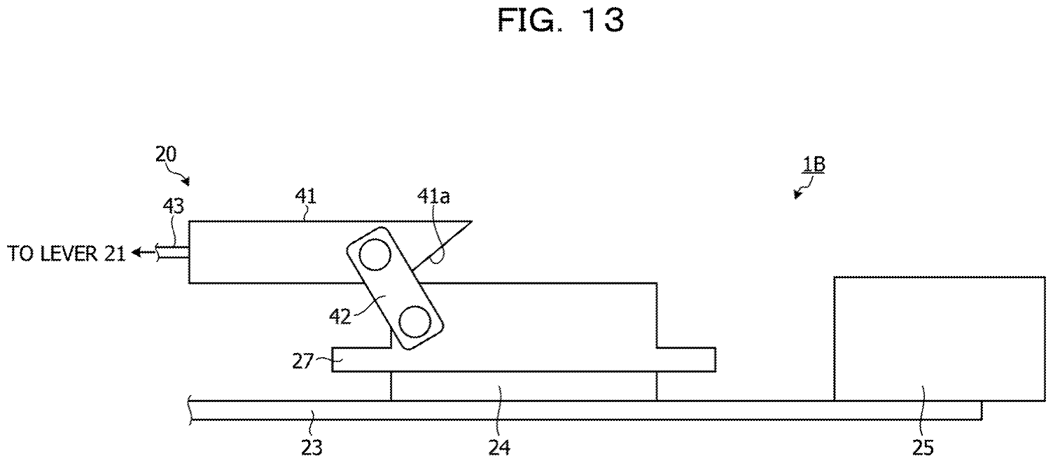

FIG. 13 is a side view illustrating one example of an internal configuration of a PIU included in a transmitting apparatus according to embodiment 3. In FIG. 13, the casing 22 of the PIU 20 is omitted for convenience of description. Furthermore, the configuration of the apparat main body 10 of embodiment 3 has a configuration similar to that, of the apparatus main body 10 of embodiment 2 and therefore detailed description thereof is omitted.

In a transmitting apparatus 1B illustrated in FIG. 13, the PIU 20 includes a displacing member 41 instead of the displacing member 26 and the fixed member 28. The displacing member 41 is a block at which an inclined surface 41a is formed at an end part. The displacing member 41 is linked to the heat transfer member 27 with the intermediary of a linking member 42 and is configured to be movable along the upper surface of the heat transfer member 27, The displacing member 41 is linked to the lever 21 (see FIG. 1) with the intermediary of a linking member 43 and displaces the cooling plate 30 held by the holding member 15 from a position higher than the electrical connector 14 and the electrical connector 25 to a position at which the cooling plate 30 gets contact with the heat transfer member 27 in conjunction with pivoting of the lever 21. For example, the displacing member 41 moves in such a direction as to get closer to the cooling plate 30 held by the holding member 15 in conjunction with the pivoting of the lever 21. For example, when the lever 21 is made to pivot in the direction with which a force in the insertion direction of the casing 22 is given to the apparatus main body 10, the displacing member 41 moves in such a direction as to get closer to the cooling plate 30 and brings the inclined surface 41a into contact with the inclined surface 301 of the cooling plate 30. Then, the displacing member 41 displaces the cooling plate 30 to the position at which the cooling plate 30 gets contact with the heat transfer member 27 by guiding the cooling plate 30 along the inclined surface 41a, If the heat transfer member 27 does not exist, the displacing member 41 may displace the cooling plate 30 to a position at which the cooling plate 30 gets contact with the electronic component 24.

### [Operation and Effects]

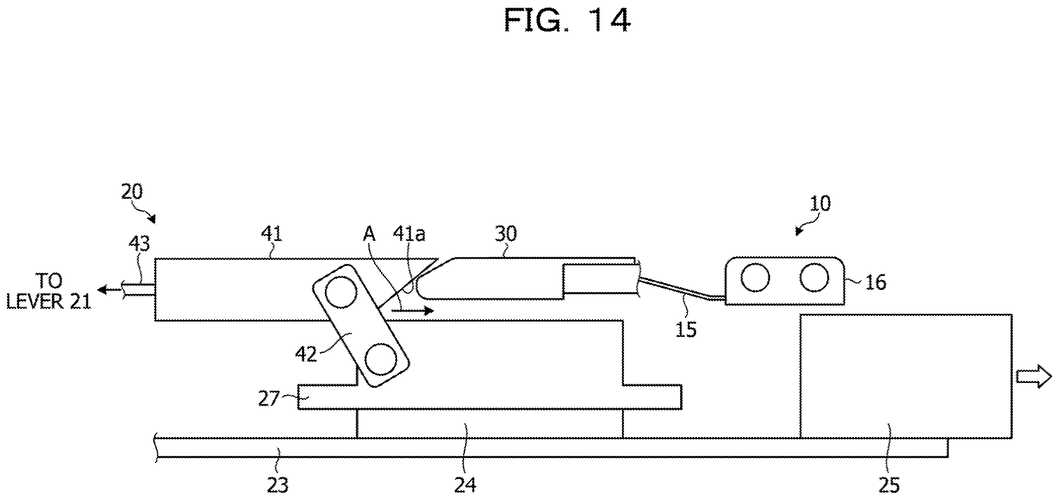

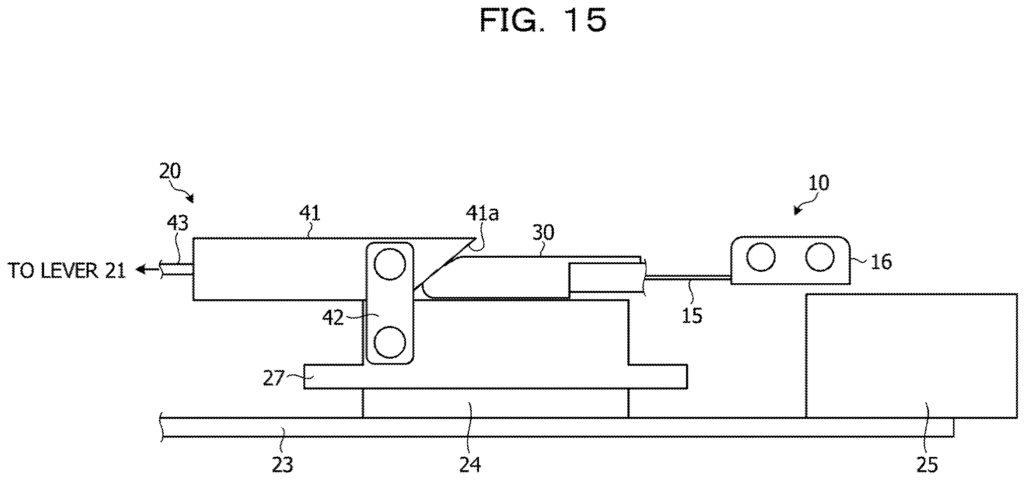

Next, operation and effects of the transmitting apparatus 1B according to the present embodiment will be described. FIG. 14 and FIG. 15 are diagrams explaining one example of the flow of operation of displacing the cooling plate 30 in embodiment 3. In FIG. 14 and FIG. 15, the casing 11 of the apparatus main body 10 and the casing 22 of the PIU 20 are omitted for convenience of description. In the state in which the casing 22 of the PIU 20 has not yet been inserted into the slot 12 of the apparatus main body 10, the holding member 15 holds the cooling plate 30 at the position higher than the electrical connector 14 and the electrical connector 25 in the slot 12 of the apparatus main body 10. First, insertion of the casing 22 of the PIU 20 into the slot 12 of the apparatus main body 10 is started. In FIG. 14, the insertion direction of the casing 22 of the PIU 20 is indicated by a white arrow.

FIG. 14 illustrates the state in which part of the casing 22 of the PIU 20 has been inserted into the slot 12 of the apparatus main body 10. In this state, the cooling plate 30 held by the holding member 15 is inserted in the gap between the electrical connector 25 and the top plate of the casing 22. Furthermore, the lever 21 is made to pivot by operation by the operator and a force in the insertion direction of the casing 22 is given to the apparatus main body 10 through the lever 21 by action of leverage. At this time, in conjunction with the pivoting of the lever 21, the displacing member 41 displaces the cooling plate 30 held by the holding member 15 from the position higher than the electrical connector 14 and the electrical connector 25 to the position at which the cooling plate 30 gets contact with the heat transfer member 27. For example, in conjunction with the pivoting of the lever 21, the displacing member 41 moves in such a direction as to get closer to the cooling plate 30 held by the holding member 15 (direction of an arrow A in FIG. 14). Then, the displacing member 41 displaces the cooling plate 30 to the position at which the cooling plate 30 gets contact with the heat transfer member 27 by guiding the cooling plate 30 along the inclined surface 41a.

FIG. 15 illustrates the state in which the casing 22 of the PIU 20 has been completely inserted into the slot 12 of the apparatus main body 10. In this state, the cooling plate 30 is in tight contact with the heat transfer member 27 due to the guiding by the displacing member 41.

As described above, in the transmitting apparatus 1B according to the present embodiment, the PIU 20 includes the displacing, member 41. The displacing member 41 is a block in which the inclined surface 41a is formed at an end part. The displacing member 41 is linked to the lever 21 with the intermediary of the linking member 43 and moves in such a direction as to get closer to the cooling plate 30 held by the holding member 15 in conjunction with the pivoting of the lever 21. Then, the displacing member 41 displaces the cooling plate 30 to the position at which the cooling plate 30 gets contact with the heat transfer member 27 by guiding the cooling plate 30 along the inclined surface 41a.

According to the configuration of the transmitting apparatus 1B, the cooling plate 30 may be brought into indirect contact with the heat generating component with the intermediary of the heat transfer member 27 in conjunction with the pivoting of the lever 21.

### [Modification Example of Embodiment 3]

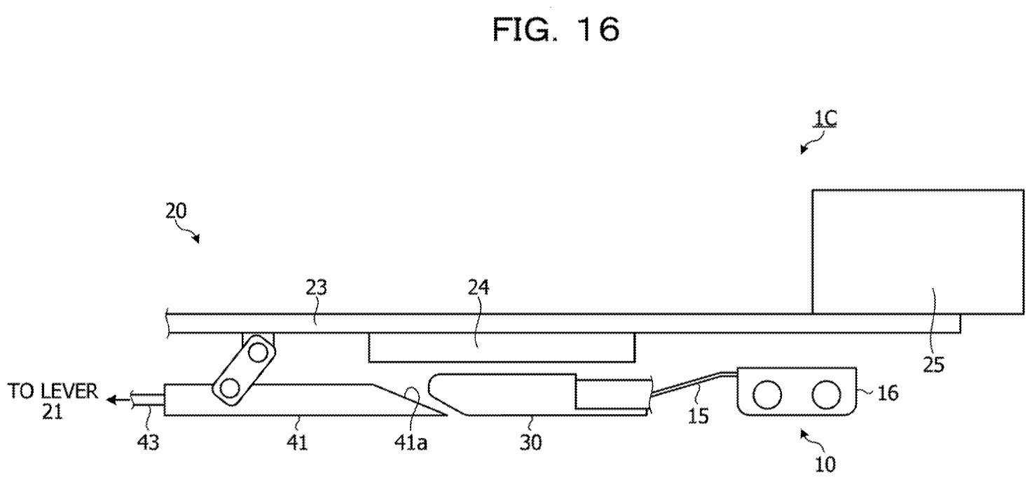

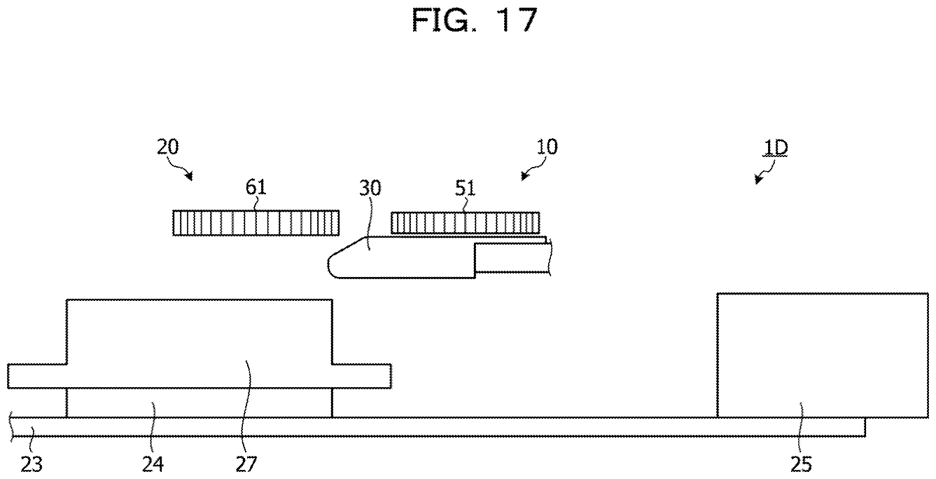

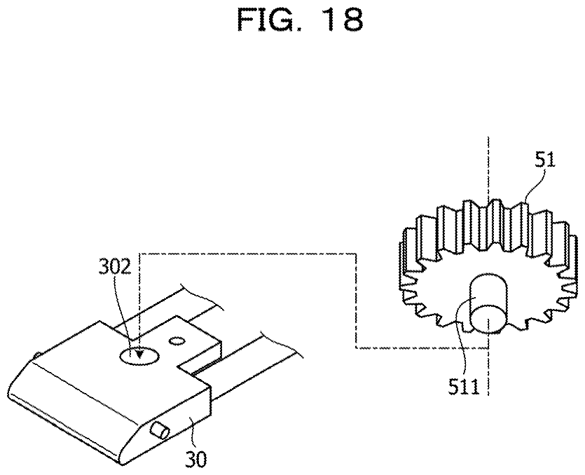

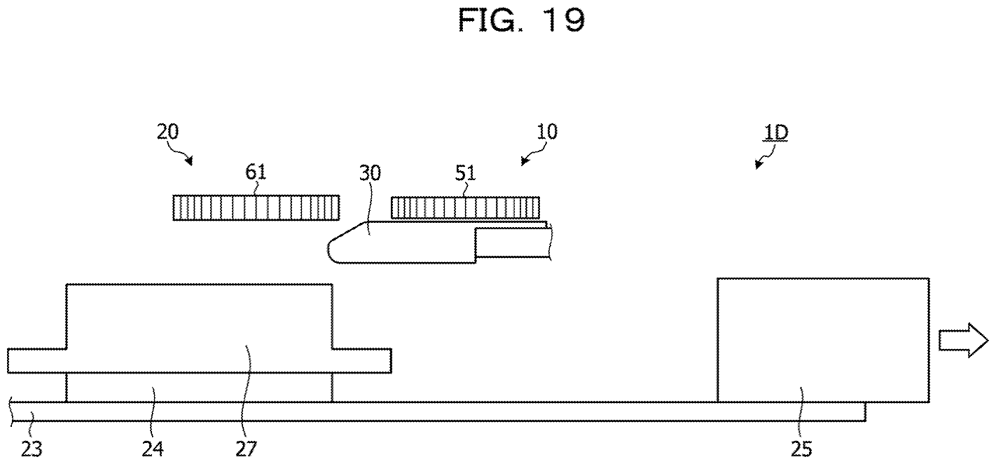

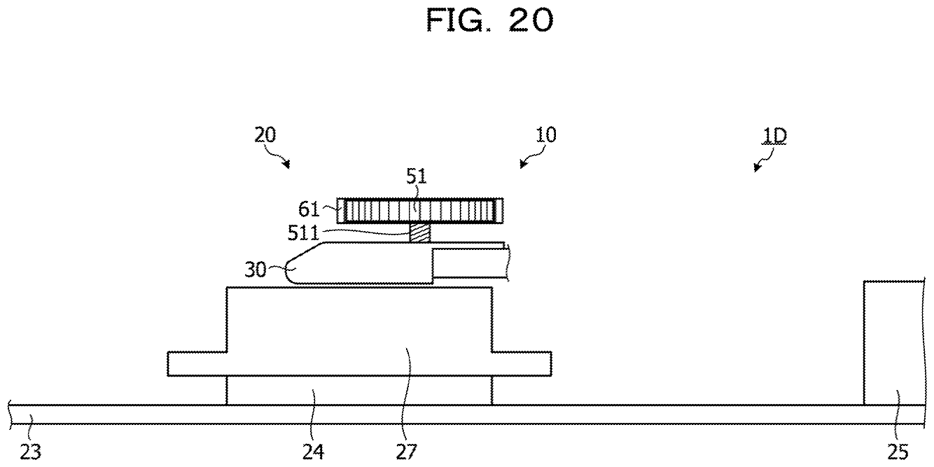

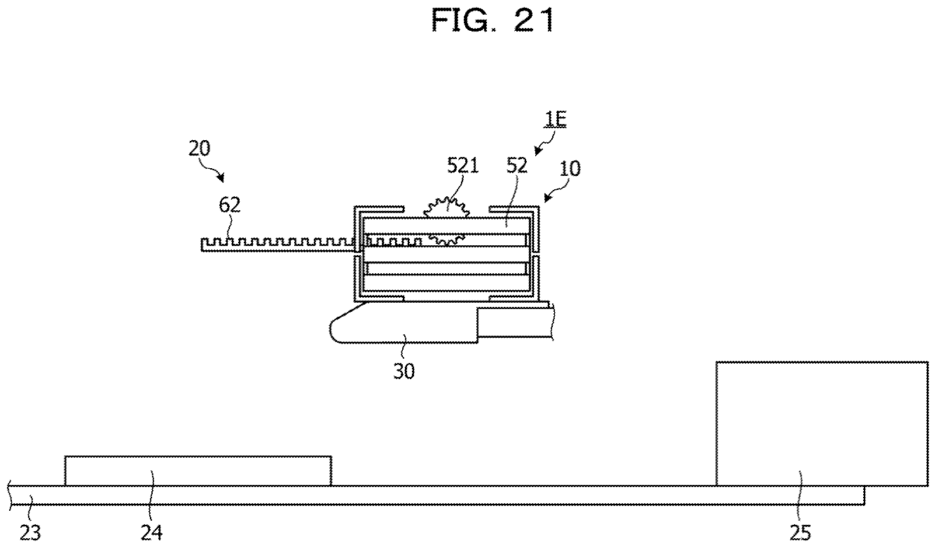

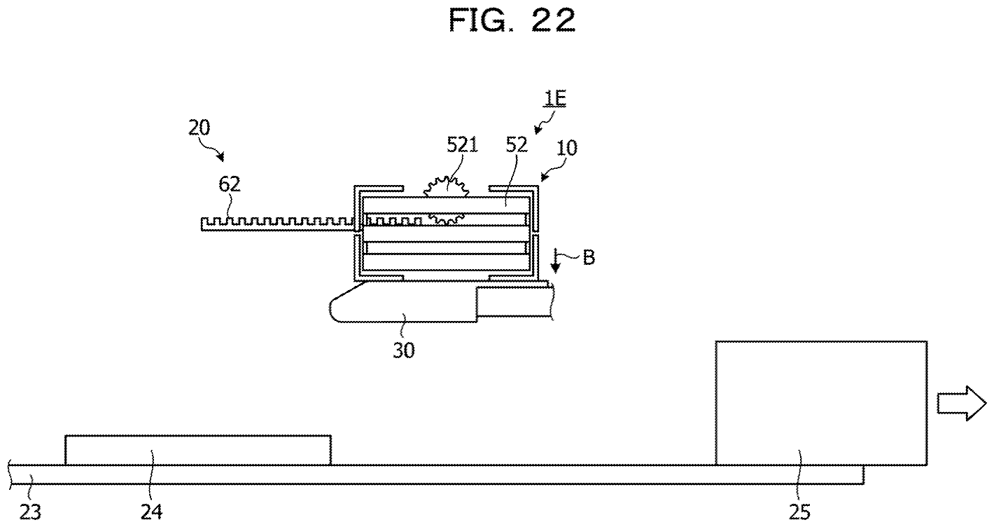

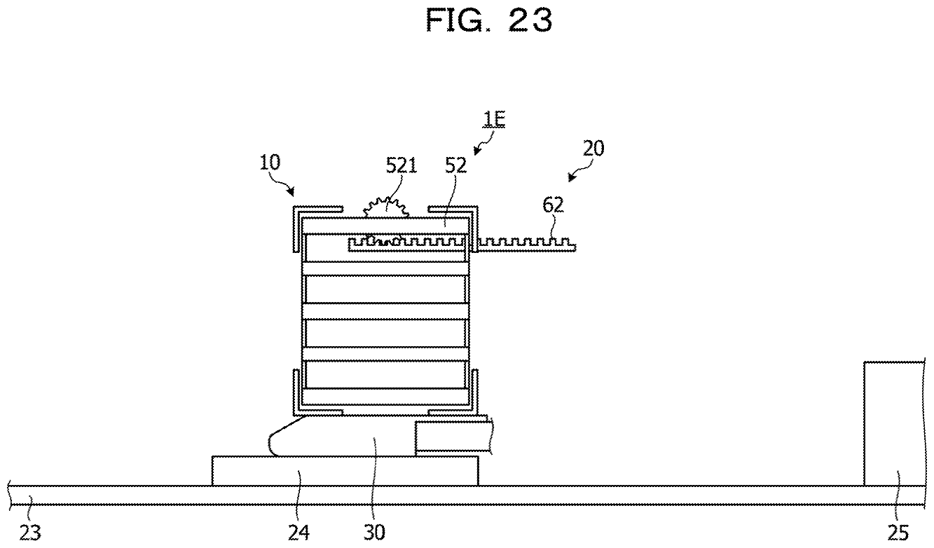

In the above-described embodiment 3, the example in which the electronic component 24 mounted on the upper surface of the substrate 23 is cooled by the cooling plate 30 is represented. However, the electronic component 24 mounted on the lower surface of the substrate 23 may be cooled by the cooling plate 30. FIG. 16 is a side view illustrating one example of an internal configuration of an apparatus main body and a PIU included in a transmitting apparatus according to a modification example of embodiment 3. In FIG. 16, the casing 11 of the apparatus main body 10 and the casing 22 of the PIU 20 are omitted for convenience of description.

In a transmitting apparatus 1C illustrated in FIG. 16, the electronic component 24 of the PIU 20 is mounted on the lower surface of the substrate 23. The displacing member 41 is configured to be movable along the lower surface of the substrate 23. Furthermore, in the transmitting apparatus 1C, the cooling plate 30 of the apparatus main body 10 is held by the holding member 15 in the state of being turned upside down.

In the transmitting apparatus 1C, the displacing member 41 is linked to the lever 21 with the intermediary of the linking member 43 and moves in such a direction as to get closer to the cooling plate 30 held by the holding member 15 in conjunction with pivoting of the lever 21. Then, the displacing member 41 displaces the cooling plate 30 to the position at which the cooling plate 30 gets contact with the heat transfer member 27 by guiding the cooling plate 30 along the inclined surface 41a. This allows the transmitting apparatus 1C to bring the cooling plate 30 into contact with the electronic component 24 mounted on the lower surface of the substrate 23 in conjunction with the pivoting of the lever 21.

### Embodiment 4

Embodiment 4 relates to a variation of the holding member and the displacing member in embodiment 2.

### [Internal Configuration of Apparatus Main Body 10 and PIU 20]

FIG. 17 is a side view illustrating one example of an internal configuration of an apparatus main body and a PIU included in a transmitting apparatus according to embodiment 4. In FIG. 17, the state in which part of the casing 22 of the PIU 20 is inserted in the slot 12 of the apparatus main body 10 is illustrated. In FIG. 17, the casing 11 of the apparatus main body 10 and the casing 22 of the PIU 20 are omitted for convenience of description.

In a transmitting apparatus 1D illustrated in FIG. 17, the apparatus main body 10 includes a holding member 51 instead of the holding member 15 and the fixed member 16. The holding member 51 is, a pinion gear and is rotatably attached to the ceiling surface of the slot 12 of the apparatus main body 10, for example. Furthermore, the holding member 51 holds the cooling plate 30 displaceably in the upward-downward direction in the slot 12 of the apparatus main body 10. The holding member 51 holds the cooling plate 30 at a position higher than the electrical connector 14 and the electrical connector 25 in the slot 12 of the apparatus main body 10.

FIG. 18 is a perspective view illustrating one example of the holding form of the cooling plate 30 in embodiment 4. As illustrated in FIG. 18, the holding member 51 includes a rotating shaft part 511 in which screw grooves are formed in the side surface as illustrated in FIG. 18. The holding member 51 holds the cooling plate 30 through engagement of the rotating shaft part 511 with a screw hole 302 formed in the cooling plate 30. The cooling plate 30 may move along the rotating shaft part 511 through rotation of the holding member 51.

Referring back to FIG. 17, in the transmitting apparatus 1D, the PIU 20 includes a displacing member 61 instead of the displacing member 26. The displacing member 61 is a rack gear and is fixed to a region corresponding to the electronic component 24 in the sidewall of the casing 22 of the PIU 20, for example. The displacing member 61 displaces the cooling plate 30 held by the holding member 51 to a position at which the cooling plate 30 gets contact with the heat transfer member 27 in conjunction with operation of inserting the casing 22 into the slot 12 of the apparatus main body 10. For example, in conjunction with the operation of inserting the casing 22, the displacing member 61 displaces the cooling plate 30 held by the holding member 51 from the position higher than the electrical connector 14 and the electrical connector 2 to the position at which the cooling plate 30 gets contact with the heat transfer member 27. In the present embodiment, the displacing member 61 engages with the holding member 51 in conjunction with the operation of inserting the casing 22. Then, the displacing member 61 displaces the cooling plate 30 to the position at which the cooling plate 30 gets contact with the heat transfer member 27 by rotating the holding member 51 and moving the cooling plate 30 in a direction toward the electronic component 24 along the rotating shaft part 511. If the heat transfer member 27 does not exist, the displacing member 61 may displace the cooling plate 30 to a position at which the cooling plate 30 gets contact with the electronic component 24.

### [Operation and Effects]

Next, operation and effects of the transmitting apparatus 1D according to the present embodiment will be described. FIG. 19 and FIG. 20 are diagrams explaining one example of the flow of operation of displacing the cooling plate 30 in embodiment 4. In FIG. 19 and FIG. 20, the casing 11 of the apparatus main body 10 and the casing 22 of the PIU 20 are omitted for convenience of description. In the state in which the casing 22 of the PIU 20 has not yet been inserted into the slot 12 of the apparatus main body 10, the holding member 51 holds the cooling plate 30 at the position higher than the electrical connector 14 and the electrical connector 25 in the slot 12 of the apparatus main body 10. First, insertion of the casing 22 of the PIU 20 into the slot 12 of the apparatus main body 10 is started. In FIG. 19, the insertion direction of the casing 22 of the PIU 20 is indicated by a white arrow.

FIG. 19 illustrates the state in which part of the casing 22 of the PIU 20 has been inserted into the slot 12 of the apparatus main body 10. In this state, the cooling plate 30 held by the holding member 51 is inserted in the gap between the electrical connector 25 and the top plate of the casing 22. The displacing member 61 engages with the holding member 51 in conjunction with the operation of inserting the casing 22. Then, the displacing member 61 displaces the cooling plate 30 to the position at which, the cooling plate 30 gets contact with the heat transfer member 27 by rotating the holding member 51 and moving the cooling plate 30 in the direction toward the electronic component 24 along the rotating shaft part 511.

FIG. 20 illustrates the state in which the casing 22 of the PIU 20 has been completely inserted into the slot 12 of the apparatus main body 10. In this state, the cooling plate 30 is in tight contact with the heat transfer member 27 due to the movement of the cooling plate 30 in association with the rotation of the holding member 51.

As described above, in the transmitting apparatus 1D according to the present embodiment, the PIU 20 includes the displacing member 61. The displacing member 61 is a rack gear and engages with the holding member 51, which is a pinion gear, in conjunction with the operation of inserting the casing 22. Then, the displacing member 61 displaces the cooling plate 30 to the position at which the cooling plate 30 gets contact with the heat transfer member 27 by rotating the holding member 51 and moving the cooling plate 30 in the direction toward the electronic component 24 along the rotating shaft part 511.

According to the configuration of the transmitting apparatus 1D, the cooling plate 30 may be brought into indirect contact with the heat generating component with the intermediary of the heat transfer member 27 in conjunction with the operation of inserting the casing 22.

### Embodiment 5

Embodiment 5 relates to a variation of the holding member and the displacing member in embodiment 2.

### [Internal Configuration of Apparatus Main Body 10 and PIU 20]

FIG. 21 is a side view illustrating one example of an internal configuration of an apparatus main body and a PIU included in a transmitting apparatus according to embodiment 5. In FIG. 21, the state in which part of the casing 22 of the PIU 20 is inserted in the slot 12 of the apparatus main body 10 is illustrated. In FIG. 21, the casing 11 of the apparatus main body 10 and the casing 22 of the PIU 20 are omitted for convenience of description. Furthermore, in the following description, it is assumed that the heat transfer member 27 is not disposed on the electronic component 24.

In a transmitting apparatus 1E illustrated in FIG. 21, the apparatus main body 10 includes a holding member 52 instead of the holding member 15 and the fixed member 16. The holding member 52 is a pantograph that may expand and contract in the upward-downward direction by rotation of a pinion gear 521 and is fixed to the ceiling surface of the slot 12 of the apparatus main body 10, for example. Furthermore, the holding member 52 holds the cooling plate 30 displaceably in the upward-downward direction in the slot 12 of the apparatus main body 10. The holding member 52 holds the cooling plate 30 at a position higher than the electrical connector 14 and the electrical connector 25 in the slot 12 of the apparatus main body 10. For example, the cooling plate 30 is fixed to the lower surface of the holding member 52 on the opposite side to the ceiling surface of the slot 12 and the cooling plate 30 is held at the position higher than the electrical connector 25 in the state in which the holding member 52 is contracted.

Furthermore, in the transmitting apparatus 1E, the PIU 20 includes a displacing member 62 instead of the displacing member 26. The displacing member 62 is a rack gear and is fixed to a region corresponding to the electronic component 24 in the sidewall of the casing 22 of the PIU 20, for example. The displacing member 62 displaces the cooling plate 30 held by the holding member 52 to a position at which the cooling plate 30 gets contact with the electronic component 24 in conjunction with operation of inserting the casing 22 into the slot 12 of the apparatus main body 10. For example, in conjunction with the operation of inserting the casing 22, the displacing member 62 displaces the cooling plate 30 held by the holding member 52 from the position higher than the electrical connector 14 and the electrical connector 25 to the position at which the cooling plate 30 gets contact with the electronic component 24. In the present embodiment, the displacing member 62 engages with the pinion gear 521 of the holding member 52 (pantograph) in conjunction with the operation of inserting the casing 22. Then, the displacing member 62 displace the cooling plate 30 to the position at which the cooling plate 30 gets contact with the electronic component 24 by rotating the pinion gear 521 and expanding the holding member 52 in a direction toward the electronic component 24. If the heat transfer member 27 is disposed on the electronic component 24, the displacing member 62 may displace the cooling plate 30 to a position at which the cooling plate 30 gets contact with the heat transfer member 27.

### [Operation and Effects]

Next, operation and effects of the transmitting apparatus 1E according to the present embodiment will be described. FIG. 22 and FIG. 23 are diagrams explaining one example of the flow of operation of displacing the cooling plate 30 in embodiment 5. In FIG. 22 and FIG. 23, the casing 11 of the apparatus main body 10 and the casing 22 of the PIU 20 are omitted for convenience of description. In the state in which the casing 22 of the PIU 20 has not yet been inserted into the slot 12 of the apparatus main body 10, the holding member 52 holds the cooling plate 30 at the position higher than the electrical connector 14 and the electrical connector 25 in the slot 12 of the apparatus main body 10. First, insertion of the casing 22 of the PIU 20 into the slot 12 of the apparatus main body 10 is started. In FIG. 22, the insertion direction of the casing 22 of the PIU 20 is indicated by a white arrow.

FIG. 22 illustrates the state in which part of the casing 22 of the PIU 20 has been inserted into the slot 12 of the apparatus main body 10. In this state, the cooling plate 30 held by the holding member 52 is inserted in the gap between the electrical connector 25 and the top plate of the casing 22. The displacing member 62 engages with the pinion gear 521 of the holding member 52 (pantograph) in conjunction with the operation of inserting the casing 22. Then, the displacing member 62 displaces the cooling plate 30 to the position at which the cooling plate 30 gets contact with the electronic component 24 by rotating the pinion gear 521 and expanding the holding member 52 in the direction toward the electronic component 24 (direction of an arrow B in FIG. 22).

FIG. 23 illustrates the state in which the casing 22 of the PIU 20 has been completely inserted into the slot 12 of the apparatus main body 10. In this state, the cooling plate 30 is in tight contact with the electronic component 24 due to the expansion of the displacing member 62.

As described above, in the transmitting apparatus 1E according to the present embodiment, the PIU 20 includes the displacing member 62. The displacing member 62 is a rack gear and engages with the pinion gear 521 of the holding member 52 (pantograph) in conjunction with the operation of inserting the casing 22. Then, the displacing member 62 displaces the cooling plate 30 to the position at which the cooling plate 30 gets contact with the electronic component 24 by rotating the pinion gear 521 and expanding the holding member 52 in the direction toward the electronic component 24.

According to the configuration of the transmitting apparatus 1E the cooling plate 30 may be brought into direct contact with the heat generating component in conjunction with the operation of inserting the casing 22.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A transmitting apparatus comprising:
an apparatus main body in which a slot is formed; and,
a plug-in unit configured to be inserted into the slot of the apparatus main body, wherein
the apparatus main body includes
a holding member that holds a cooling plate displaceably in an upward-downward direction in the slot of the apparatus main body, and
the plug-in unit includes
a casing allowed to be inserted and removed into and from the slot of the apparatus main body,
a substrate that is housed in the casing and on which a heat generating component is mounted, and
a displacing member that displaces the cooling plate held by the holding member to a position at which the cooling plate gets contact with the heat generating component or a position at which the cooling plate gets contact with a heat transfer member disposed on the heat generating component in conjunction with operation of inserting the casing into the slot of the apparatus main body.

2. The transmitting apparatus according to claim 1, wherein
the apparatus main body further includes a first electrical connector,
the plug-in unit further includes a second electrical connector that is mounted on the substrate and is coupled to the first electrical connector of the apparatus main body in a state in which the casing is inserted in the slot of the apparatus main body,
the holding member holds the cooling plate at a position higher than the first electrical connector and the second electrical connector in the slot of the apparatus main body, and
the displacing member displaces the cooling plate held by the holding member from the position higher than the first electrical connector and the second electrical connector to the position at which the cooling plate gets contact with the heat generating component or the position at which the cooling plate gets contact with the heat transfer member in conjunction with the operation of inserting the casing.

3. The transmitting apparatus according to claim 1, wherein
the holding member is a plate spring, and
the displacing member is a plate spring and displaces the cooling plate held by the holding member to the position at which the cooling plate gets contact with the heat generating component or the position at which the cooling plate gets contact with the heat transfer member by elastically pressing the cooling plate in a direction toward the heat generating component in conjunction with the operation of inserting the casing.

4. The transmitting apparatus according to claim 1, wherein
the plug-in unit further includes a lever that is pivotally disposed on the casing and is operated to pivot in the operation of inserting the casing,
the holding member is a plate spring, and
the displacing member is a block in which an inclined surface is formed at an end part, is linked to the lever with intermediary of a linking member, and displaces the cooling plate to the position at which the cooling plate gets contact with the heat generating component or the position at which the cooling plate gets contact with the heat transfer member by moving in such a direction as to get closer to the cooling plate held by the holding member and guiding the cooling plate along the inclined surface in conjunction with pivoting of the lever.

5. The transmitting apparatus according to wherein
the holding member is a pinion gear, includes a rotating shaft part in which screw grooves are formed in a side surface, and holds the cooling plate through engagement of the rotating shaft part with a screw hole formed in the cooling plate, and
the displacing member is a rack gear and, in conjunction with the operation of inserting the casing, engages with the holding member and displaces the cooling plate to the position at which the cooling plate gets contact with the heat generating component or the position at which the cooling plate gets contact with the heat transfer member by rotating the holding member and moving the cooling plate in a direction toward the heat generating component along the rotating shaft part.

6. The transmitting apparatus according to claim 1, wherein
the holding member is an expanding-contracting mechanism capable of expanding and contracting in the upward-downward direction by rotation of a pinion gear and includes a lower surface to which the cooling plate is fixed, and
the displacing member is a rack gear and, in conjunction with the operation of inserting the casing, engages with the pinion gear of the holding member and displaces the cooling plate to the position at which the cooling plate gets contact with the heat generating component or the position at which the cooling plate gets contact with the heat transfer member by rotating the pinion gear and expanding the holding member in a direction toward the heat generating component.

7. A plug-in unit inserted into a slot of an apparatus main body in which the slot is formed and that includes a holding member that holds a cooling plate displaceably in an upward-downward direction in the slot, the plug-in unit comprising:
a casing configured tube allowed to be inserted and removed into and from the slot of the apparatus main body;
a substrate configured to be housed in the casing and on which a heat generating component is mounted; and
a displacing member configured to displace the cooling plate held by the holding member to a position at which the cooling plate gets contact with the heat generating component or a position at which the cooling plate gets contact with a heat transfer member disposed on the heat generating component in conjunction with operation of inserting the casing into the slot of the apparatus main body.

8. The plug-in unit according to claim 7, wherein
the holding member is a plate spring, and
the displacing member is a plate spring and displaces the cooling plate to the position at which the cooling plate gets contact with the heat generating component or the position at which the cooling plate gets contact with the heat transfer member by elastically pressing the cooling plate held by the holding member in a direction toward the heat generating component in conjunction with the operation of inserting the casing.
